(19) United States
(12) Patent Application Publication
(10) Pub. No.: US 2026/0235251 A1
(43) Pub. Date: Aug. 13, 2026

(54) DEVICE FOR REMOVABLY ATTACHING A PIECE OF EQUIPMENT AND CORRESPONDING PIECE OF EQUIPMENT

(71) Applicant: SAFRAN ELECTRONICS & DEFENSE, Paris (FR)

(72) Inventors: Maxime BOUCARD, MOISSY-CRAMAYEL (FR); Alain GIORGIO, MOISSY-CRAMAYEL (FR)

(21) Appl. No.: 19/471,896

(22) PCT Filed: Apr. 12, 2024
(86) PCT No.: PCT/EP2024/060035

§ 371 Date: Oct. 2, 2025

(30) Foreign Application Priority Data
Apr. 14, 2023 (FR) FR2303742

(51) Int. Cl. F16M 11/04; F16B 1/00; F16M 11/22; G01P 1/00

(52) U.S. Cl. CPC F16M 11/04; F16B 1/00; F16M 11/22; F16M 2200/08; G01P 1/00

(57) ABSTRACT

The invention relates to a device for removably attaching a piece of equipment (E), comprising a base (200) and a frame (100) to which the piece of equipment is rigidly connected; the frame (100) having a first side (101) and a second side (102), opposite each other with respect to a first axis (A1) of the frame (100), and a base plate (103) extending between the sides (101, 102) in parallel with the first axis (A1) in order to rest on an upper surface (203) of the base (200). The device comprises at least a first abutment (104) arranged on the frame (100) in order to be engaged under a hook (204) rigidly connected to the base (200), and a second abutment (106) arranged on the frame (100) in order to engage with a tie rod (206) connected to the base (200).

The present invention relates to the field of the removable attachment of equipment—in particular, electronic, electromechanical, or optronic equipment—for example, inertial measurement units.

### BACKGROUND OF THE INVENTION

It is common to install such equipment in a vehicle by attaching a base in the vehicle and mounting the equipment in a frame that will be attached to the base. Often, several bases are joined together to form a rack allowing the equipment to be grouped together in the same part of the vehicle, such as an avionics bay, in the case of an aircraft.

The frame generally comprises first and second opposing sides with respect to a first axis of the frame, and a base plate extending between the sides in parallel with the first axis to rest on an upper surface of the base. The base comprises, for example, pins in parallel with the first axis and engaged in recesses in the frame and a clamping system for positioning and holding the frame on the base.

It is necessary that the fastening device formed by the base and the frame does not contain any fragile parts or parts exposed to any shocks, before the frame is assembled onto the base, is reliable and robust after assembly, and does not cause hyperstaticism that may interfere with the operation of the equipment, particularly, when said equipment is a sensitive measuring equipment.

### AIM OF THE INVENTION

A particular aim of the invention is to provide an attachment device that meets the above requirements, at least in part.

### SUMMARY OF THE INVENTION

To this end, the invention relates to a device for removably attaching a piece of equipment, comprising a base and a frame to which the piece of equipment is rigidly connected; the frame having a first side and a second side, opposite each other with respect to a first axis of the frame, and a base plate extending between the sides in parallel with the first axis in order to rest on an upper surface of the base. The device comprises at least:
a first abutment arranged on the first side of the frame to be engaged with respect to the first axis under a hook integral with the base and projecting from the upper surface of it, the hook and the first abutment having first surfaces, at least one of which is inclined to press the base plate against the upper surface when the first surfaces bear against each other;
a second abutment arranged on the second side of the frame, comprising a notch to receive a portion of a tie rod having an end section bearing on the base, the second abutment and the tie rod having second surfaces at least one of which is inclined and the tie rod being inclined to bear: the second surfaces against each other, the first surfaces against each other, and the base plate against the upper surface of the base.

The inclination of the abutment surfaces of the tie rod thus contributes to creating intimate contact between the second abutment surfaces, the first abutment surfaces, and between the base plate and the upper surface of the base. Thus, the frame is accurately and reliably positioned and held on the base.

According to the optional features, used individually or fully or partly in combination:
the first abutment is arranged on the first side of the frame above the base plate and/or the second abutment is arranged on the second side of the frame and above the base plate.
the first abutment is arranged in a recess of the first side;
the first inclined surface forms an angle of approximately 45° with the base plate and the upper surface of the base and/or the second inclined surface forms an angle of approximately 45° with the base plate and the upper surface of the base.
the tie rod forms an angle of approximately 45° with the base plate and the upper surface of the base;
the second surface of the second abutment is concave, curved about a second axis perpendicular to the first axis and in parallel with the base plate, the second surface carried by the tie rod is convex and curved correspondingly to the second concave surface.
the second convex surface is part of a plate interposed between a shoulder of the tie rod and the second concave surface;
the tie rod is a screw with a head forming the shoulder and an end hinged to the base about a third axis in parallel with the second axis;
the upper surface of the base and the base plate are provided with elements for relative centring of the frame and the base;
the centring elements comprise at least one raised element projecting from the upper surface of the base to define an alignment reference of the first axis and the base plate comprises a groove in parallel with the first axis to receive said raised element.
there are two raised elements in the form of two pins.

It is thus possible to achieve an assembly of the attachment device formed by the base and the frame that is simplified, repeatable, and less dependent on manipulating an operator (clamping tension different from one individual to another). The absence of a projecting part on the frame limits the risk of them deteriorating and the risk of injury to the operator.

The invention also relates to equipment mounted on a frame of such an attachment device.

Other features and advantages of the invention will become apparent on reading the following description of particular and non-limiting embodiments of the invention.

### BRIEF DESCRIPTION OF THE DRAWINGS

Reference will be made to the accompanying drawings, among which:

FIG. 1 is a perspective view of a base of the device of the invention;

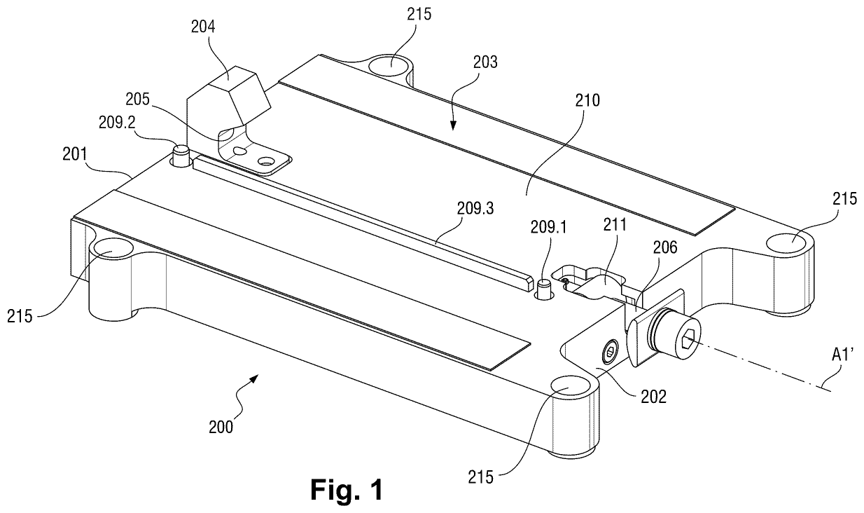

FIG. 2 is a kinematic diagram of the attachment device according to the invention after a frame has been attached to this base;

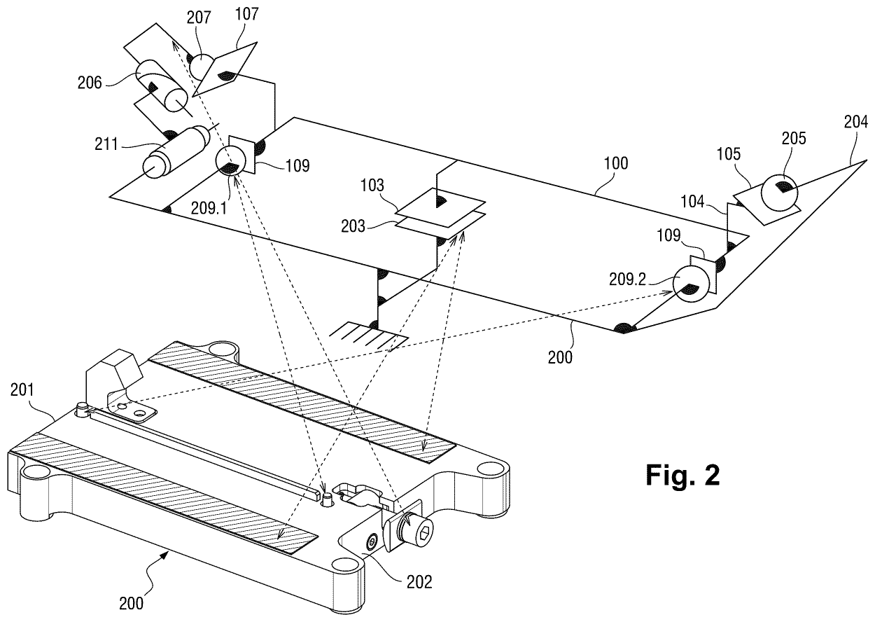

FIG. 3 is a perspective view from below of the frame;

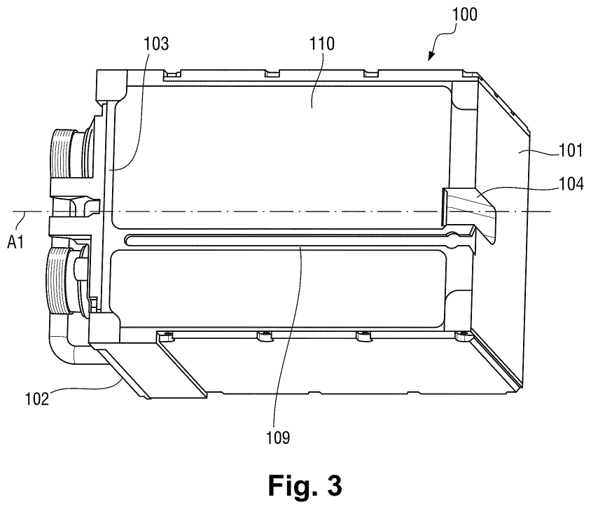

FIG. 4 is a perspective view of the attachment device being assembled, showing, more particularly, a first side of the frame;

FIG. 5 is a view similar to that in FIG. 4, but partial and enlarged, after the frame is slightly moved with respect to the base;

FIG. 6 is a view similar to that in FIG. 5, after the frame is completely moved with respect to the base;

FIG. 7 is a partial longitudinal cross-sectional view, showing the assembly of the frame with the base of an attachment device according to a variant embodiment;

FIG. 8 is a partial perspective view of the attachment device being assembled, showing, more particularly, a second side of the frame;

FIG. 9 is a view similar to that in FIG. 8, of the attachment device after the frame is assembled on the base;

FIG. 10 is a partial perspective view of the assembled attachment device from below.

### DETAILED DESCRIPTION OF THE INVENTION

The invention is described here, according to an embodiment, in application to attaching a piece of equipment E in a vehicle: the piece of equipment E is, in this case, an inertial measurement unit. It must be noted that an inertial measurement unit comprises: linear inertial sensors, namely accelerometers, arranged with respect to the axes of a measurement reference frame; angular inertial sensors, namely gyroscopes or gyrometers, arranged to measure angular movements of the measurement reference frame with respect to an inertial reference frame; and an electronic processing unit connected to the inertial sensors to provide signals representative of an attitude and a movement of the inertial measurement unit in the inertial reference frame. This is an example of equipment that may be used with the invention, the attachment device being able to be used with any type of equipment, in particular, electronic, electromechanical or optronic equipment.

With reference to the figures, the removable attachment device of the invention comprises, firstly, a frame 100 and, secondly, a base 200.

In this case, the frame 100 is in the form of a parallelepiped containing the equipment E and comprising a first side 101 and a second side 102 which are opposite each other with respect to a first axis A1 of the frame 100, and a base plate 103 that extends between the sides 101 and 102 in parallel with the first axis A1.

The first side 101 comprises, in the vicinity of the base plate 103, a recess in which a heel 104 projects with a slightly spherical convex upper surface forming a first abutment surface 105. The heel 104 extends above the base plate 103 and the first surface of the abutment 105 is inclined to form an acute angle with the base plate 103, in this case, 45°.

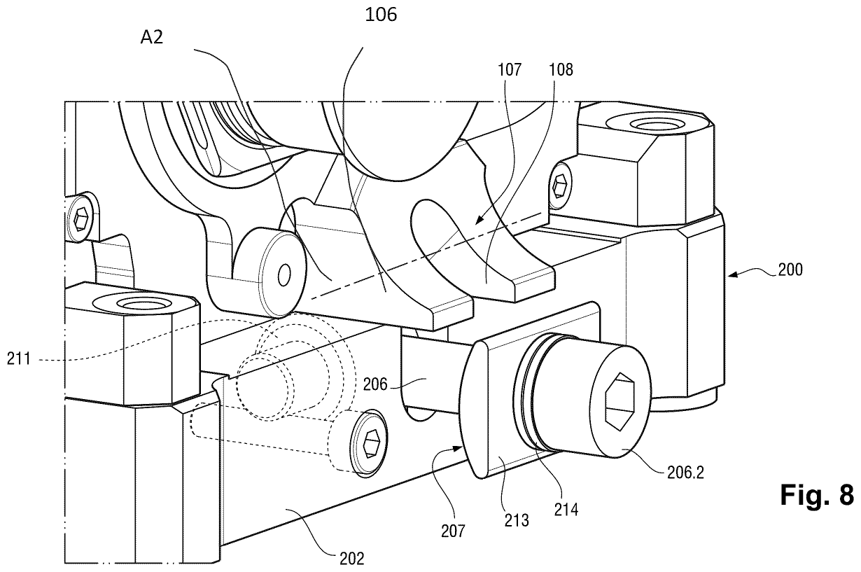

The second side 102 comprises, in the vicinity of the base plate 103, a latch 106 (visible in FIGS. 8 to 10) projecting from the second side 102 with respect to the first axis A1. The latch 106 has a slightly cylindrical concave upper surface forming a second abutment surface 107: the second abutment surface 107 is, in this case, curved about a second axis A2 perpendicular to the first axis A1 and in parallel with the base plate 103. The latch 106 extends substantially above the base plate 103 (its lower surface is flush with the base plate 103) and the second abutment surface 107 is inclined to form an acute angle with the base plate 103, in this case, of 45°. The latch 106 is provided with a notch 108 that is vertical and in parallel with the first axis A1, dividing the second abutment surface 107 into two parts.

A groove 109 in parallel with the first axis A1 extends in the base plate 103 and has one end opening onto the first side 101 and an opposite blind end. Depressions 110 have also been formed in the base plate 103 such that the base plate 103 may rest on a support surface essentially by its corners.

In this example, the base 200 is in the form of a parallelepiped comprising a first side 201 and a second side 202 which are opposite each other with respect to a first axis A1′ of the base 200, and an upper surface 203 that extends between the sides 201, 202 in parallel with the first axis A1′.

On an edge of the upper surface 203 adjacent to the first side 201, a hook 204 is attached, projecting from the upper surface 203 and comprising, opposite the upper surface 203, a first abutment surface 205 inclined to form an acute angle, 45° in this case, with the upper surface 203.

A tie rod 206 is mounted in the vicinity of the second side 202 and has a first end section 206.1 hinged to the base 200 and a second end section 206.2 forming a head with a shoulder for bearing via a second abutment surface 207 on the second abutment surface 107 of the frame 100. More specifically, the first end section is threaded and screwed into a cylinder 211 mounted in a lower recess 212 of the base 200 to pivot about a third axis A3 in parallel with the second axis A2 and positioned between the first side 201 and the second side 202 but closer to the latter. It must be noted that a pin passes through the first end section 206.1 such that the tie rod 206 is captive in the cylinder 211. The second abutment surface 207, in this case, is part of a plate 213 on which the shoulder of the second end section 206.2 bears via an anti-loosening washer 214.

The upper surface 203 comprises elements for relative centring of the frame 100 and the base 200 on the first axes A1, A1′. The relative centring elements project from the top surface 203 and, in this case, comprise two pins 209.1, 209.2 between which a tab 209.3 extends to define an alignment reference of the first axis A1, A1′. A depression 210 has also been formed in a central strip of the upper surface 203 such that only two side strips of the upper surface 203 may support the base plate 103.

In use, the base 200 is previously attached in the vehicle, for example, by means of screws passing through the holes 215 made in the base 200 perpendicularly to the upper surface 203.

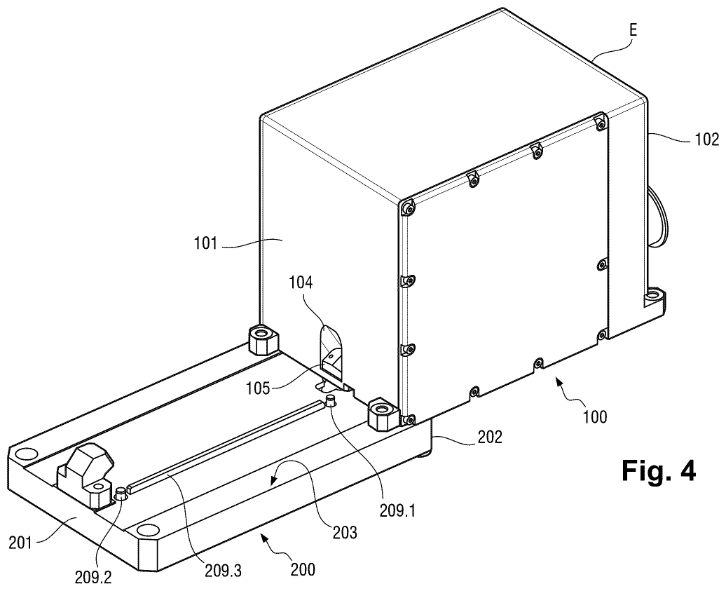

The frame 100 is attached, firstly, by bringing the base plate 103 in the vicinity of the first side 101 to bear against the upper surface 203 in the vicinity of the second side 202 (FIG. 4), the tie rod 206 being in a low position in which it extends substantially horizontally at a level lower than the upper surface 203.

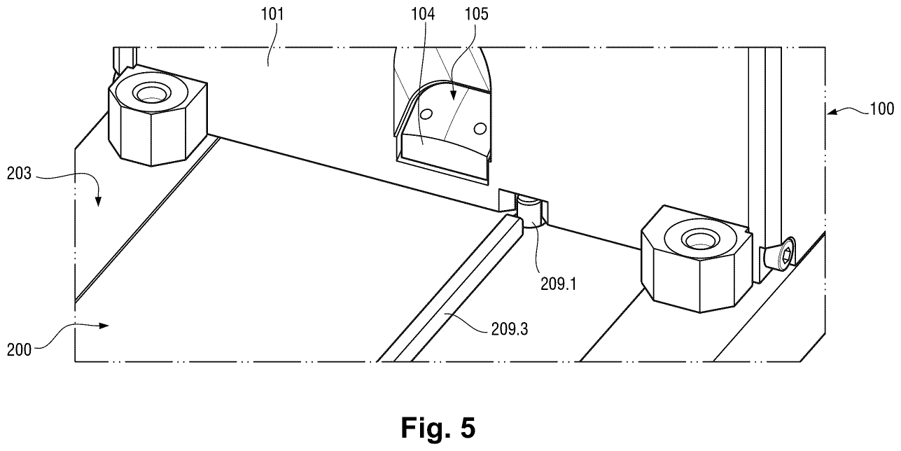

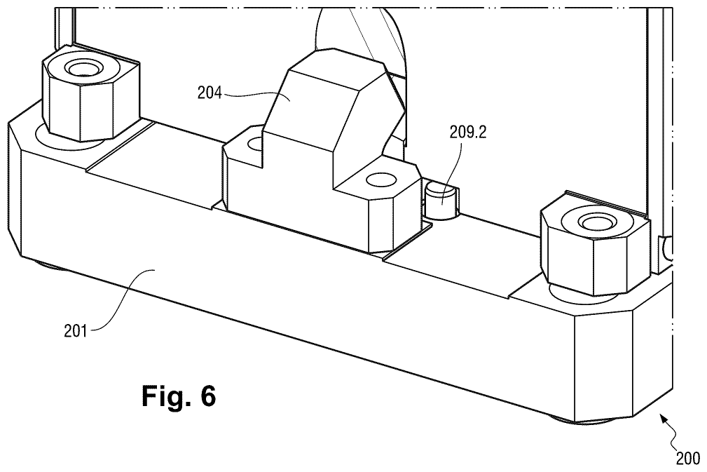

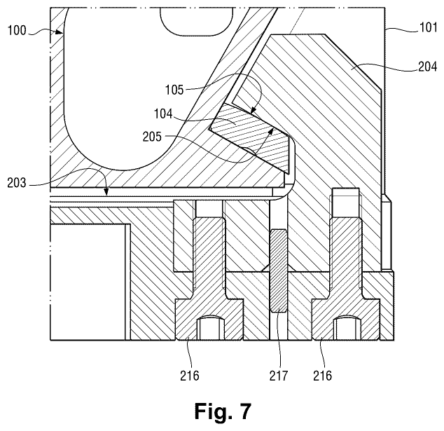

The frame 100 is then moved towards the first side 201 of the base 200 by inserting into the groove 109, the pin 209.1 (FIG. 5), then the tab 209.3, and then the pin 209.2 (FIG. 6). The first abutment surfaces 105, 205 are then in contact with each other. In FIG. 6, it can be seen that the hook 204 remains outside of the heel 104. In a variant, as shown in FIG. 7, it is possible to have a heel 104 with a greater depth to allow it to completely accommodate the hook 204, the first side 101 of the frame then extending in the extension of the first side 201 of the base when the frame 100 and the base 200 are assembled.

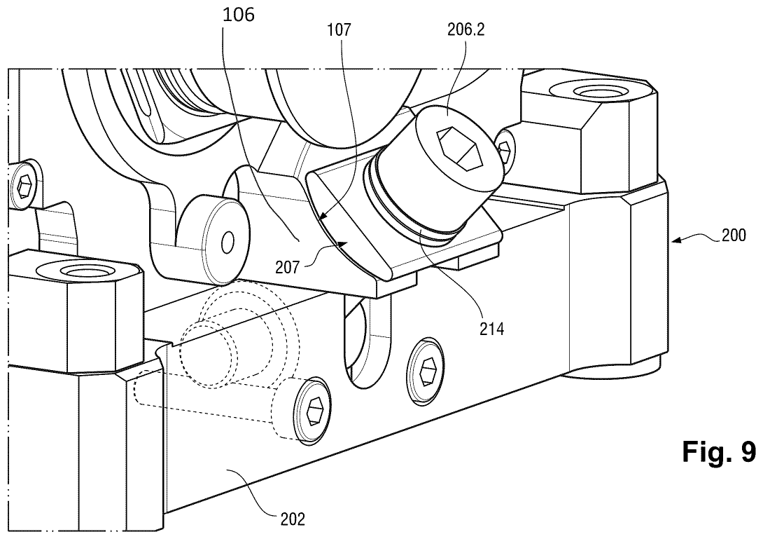

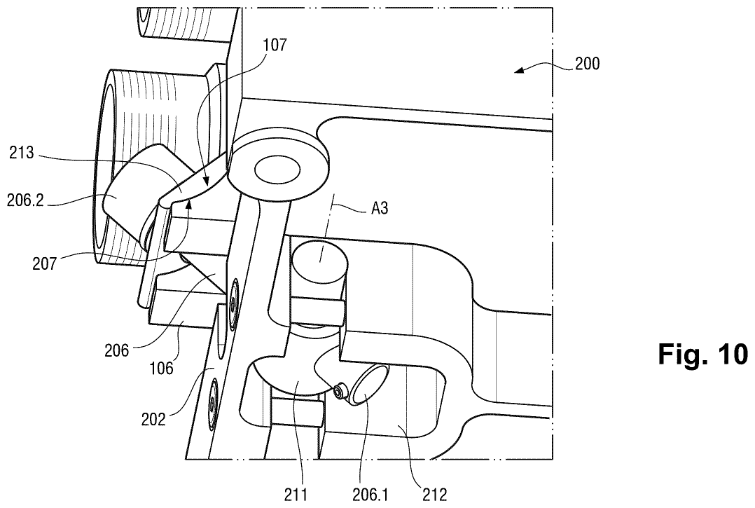

The tie rod 206, in the low position for positioning the frame 100 (FIG. 8), is then folded down towards the frame 100 in order to insert it into the notch 108 and place the second abutment surfaces 107, 207 opposite each other. The tie rod 206 is then screwed to tighten the second abutment surfaces 107, 207 against each other (see FIGS. 9 and 10). It can be seen that the tie rod 206 in this position forms an angle of approximately 45° with the upper surface 203 of the base 200 and the base plate 103.

Thus, when the frame and the base are assembled:
the heel 104 forming the first abutment of the frame is engaged under the hook 204 integral with the base 200 and projecting from its upper surface, and the first abutment surfaces 105, 205 bear against each other so as to oppose axial movement of the frame 100 with respect to the base 200 and to press the base plate 103 against the upper surface 203 of the base 200;
the tie rod 206 exerts a force on the latch 106 and the second abutment surfaces bear against each other so as to oppose an axial movement of the frame 100 with respect to the base 200 and to bear the second abutment surfaces 107, 207 against each other, and the base 103 against the upper surface 203 of the base 200;
the pins 209.1, 209.2 are received in an adjusted manner in two sections of the groove 109 and ensure the alignment of the axes A1, A1′. Preferably, the pin 209.2 has a diameter greater than the pin 209.1 such that the length of groove receiving the pin 209.2 is wider than the pin 209.1 (in this case, by one millimetre): there is thus no risk of the pin 209.1 damaging the length of groove receiving the pin 209.2, or vice-versa, when the pin 209.1 is engaged in the groove 109. The open end of the groove 109 is flared and the tab 209. 3 serves only to guide the frame 100 roughly during its movement along the base 200 so as to hold the flared end facing the pin 209.2. This prevents the first side 101 from striking the pin 209.2.

It is thus understood that, in the case of an inertial measurement unit:
the heading of the inertial measurement unit is provided by the line of travel defined by the pins 209.1, 209.2;
the roll and pitch orientation is provided by the planar contact of the base plate 103 against the upper surface 203 of the base 200.

It is also understood that the planar contact is forced by the inclined clamping on the second side and the inclined bearing on the first side.

It must be noted that the frame 100 does not comprise any element projecting from the base plate 103: it is thus possible to position the frame flat on any planar support, without any risk of damaging such projecting elements.

It must also be noted that only the second side has a projecting part, that facilitates any manipulations of the frame and limits the risk of damaging the protruding element.

The depressions of the base plate 103 and of the upper surface 203 make it possible to limit the areas of the base plate 103 in contact with the upper surface 203 of the base 200 when the frame 100 rests on the base 200. This makes it possible to have planar contact.

Naturally, the invention is not limited to the embodiments described, but covers any variant included within the scope of the invention as defined by the claims.

In particular, the structure of the attachment device may be different to that described.

The abutment surfaces may be integral with the heel 104 and the latch 106 when the latter are made of hard materials (for example, steel), or they may be part of a component connected to the heel 104 and the latch 106 when the latter are made of softer materials (for example, aluminium). The hook 204 is preferably made of steel, as is the plate 213.

The hook 204 is, in this case, attached to the base 200, more precisely, attached by screws 216 passing through the base 200 from below, a pin 217 itself being engaged in the base 200 and the hook 204 in parallel with the screws 216 to take up the shearing forces and the forces in parallel with the axis A1. It is possible to envisage other attachment methods, for example without a pin or by welding. In addition, the hook 204 may be integral with the base 200.

Instead of a threaded end, the tie rod 206 may have a shouldered end connected to the cylinder 211 by an abutment section. The tie rod may be an eye-bolt or have a toggle-clamp-type clamping system. The tie rod may be an element that is separate from the base and that is screwed into the base at the end of assembly.

It is stated that the abutment surfaces form an angle of 45° with the base plate 103 and the upper surface 203 of the base 200. This angle includes the ideal precise value of 45°, and also values within a few degrees of this.

Preferably, the tie rod 206 forms an angle of approximately 45° with the base plate 103 and the upper surface 203 of the base 200. An angle greater or less than 45° is obviously possible.

The relative centring elements of the frame 100 and of the base 200 may have any suitable shape and, for example, may be produced in the form of one or more cubic raised elements, etc.

Preferably, there are two raised elements in the form of two pins, but different numbers and/or different shapes are possible.

The abutment surfaces may have planar or non-planar shapes to provide planar contact, linear contact, or point contact between them.

The housings of the pins in the frame may be inserts, made of steel, for example, attached under the frame.

The tab 209. 3 may be replaced by one or two side edges projecting from the top surface 203 to guide any movement of the frame 100 in parallel with the first axis A1.

Two heels 104 and two latches 106 may be provided on the frame 100, and two hooks 204 and two tie rods 206 on the base 200.

1. A device for removably attaching a piece of equipment (E), comprising, on the one hand, a base (200) and, on the other hand, a frame (100) to which the equipment is rigidly connected; the frame (100) having a first side (101) and a second side (102) opposite each other with respect to a first axis (A1) of the frame (100), and a base plate (103) extending between the sides (101, 102) in parallel with the first axis (A1) in order to rest on an upper surface (203) of the base (200); the device being characterised in that it comprises at least:
a first abutment (104) arranged on the first side (101) of the frame (100) to be engaged with respect to the first axis (A1) under a hook (204) integral with the base (200) and projecting from its upper surface (203), the hook (204) and the first abutment (104) having first surfaces (105, 205), at least one of which is inclined to press the base plate (103) against the upper surface (203) when the first surfaces (105, 205) bear against each other;
a second abutment (106) arranged on the second side (102) of the frame (100), comprising a notch (108) to receive a portion of a tie rod (206) having an end section (206.1) bearing on the base (200), the second abutment (106) and the tie rod (206) having second surfaces (107, 207) at least one of which is inclined and the tie rod (206) being inclined to bear: the second surfaces (107, 207) against each other, the first surfaces (105, 205) against each other, and the base plate (103) against the upper surface (203) of the base (200).

2. The device according to claim 1, wherein the first abutment (104) is arranged on the first side (101) of the frame above the base plate (103) and/or the second abutment (106) is arranged on the second side (102) of the frame (100) and above the base plate (103).

3. The device according to claim 1 or claim 2, wherein the first abutment (104) is arranged in a recess of the first side (101).

4. The device according to any one of the preceding claims, wherein the first inclined surface (105, 205) forms an angle of approximately 45° with the base plate (103) and the upper surface (203) of the base (200) and/or the second inclined surface (107, 207) forms an angle of approximately 45° with the base plate (103) and the upper surface (203) of the base (200).

5. The device according to any one of the preceding claims, wherein the second surface (107) of the second abutment (106) is concave, curved about a second axis (A2) perpendicular to the first axis (A1) and in parallel with the base plate (103), the second surface (207) carried by the tie rod (206) is convex and curved correspondingly to the second concave surface.

6. The device according to claim 6, wherein the second convex surface (207) is part of a plate (213) interposed between a shoulder of the tie rod (206) and the second concave surface (107).

7. The device according to claim 7, wherein the tie rod (206) is a screw with a head forming the shoulder and an end (206.1) hinged to the base (200) about a third axis (A3) in parallel with the second axis (A2).

8. The device according to any one f the preceding claims, wherein the upper surface (203) of the base (200) and the base plate (103) are provided with elements for relatively centring the frame (100) and the base (200).

9. The device according to claim 8, wherein the centring elements comprise at least one raised element (209.1, 209.2) projecting from the upper surface (203) of the base (200) to define an alignment reference of the first axis (A1) and the base plate (103) comprises a groove (109) in parallel with the first axis to receive said raised element.

10. The equipment (E) mounted on a frame (100) of a device according to any one of the preceding claims.
